(19) United States
(12) Patent Application Publication
(10) Pub. No.: US 2024/0368801 A1
(43) Pub. Date: Nov. 7, 2024

(54) DOPED PARTICULATE SILICON PARTICLE SIZE SELECTION

(71) Applicant: GlobalWafers Co., Ltd., Hsinchu (TW)

(72) Inventors: JunHwan Ji, Cheonan-si (KR); JaeWoo Ryu, Plano, TX (US); Carissima Marie Hudson, Saint Charles, MO (US)

(21) Appl. No.: 18/623,268

(22) Filed: Apr. 1, 2024

Related U.S. Application Data
(60) Provisional application No. 63/499,307, filed on May 1, 2023.

(51) Int. Cl. C30B 15/04; C30B 29/06; C30B 35/00

(52) U.S. Cl. CPC C30B 15/04; C30B 29/06; C30B 35/00

(57) ABSTRACT

Methods for doping a silicon melt with doped particulate silicon are disclosed. Maximum particle size of the doped particulate silicon may be controlled based on the impact region of the doped particulate silicon on the silicon melt.

### CROSS-REFERENCE TO RELATED APPLICATIONS

This application claims the benefit of U.S. Provisional Patent Application No. 63/499,307, filed May 1, 2023, which is incorporated herein by reference in its entirety.

### TECHNICAL FIELD

The technical field of the disclosure relates to methods for doping a silicon melt with doped particulate silicon.

### BACKGROUND

Doping of a silicon melt with solid-phase dopant is desirable as it achieves near 100% doping efficiency compared to gas-phase doping which is much less efficient. Solid-phase doping also results in more accurate doping control. However, solid-phase doping has a high potential for loss of zero dislocation (“LZD”) in the ingot due to the relatively long melting time of solid dopant at the melt free surface. Floating solid dopant can hit the growing crystal to cause LZD.

A need exists for methods for doping a silicon melt with solid dopant which reduce or eliminate loss of zero dislocation in the growing crystal.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for forming a single crystal silicon ingot. An initial charge of polycrystalline silicon is added to a crucible. The crucible has a floor and a sidewall that extends from the floor. The initial charge of polycrystalline silicon is heated to cause a silicon melt to form in the crucible. The silicon melt has a surface. A seed crystal is contacted with the surface of the silicon melt. The seed crystal is withdrawn from the melt to grow a single crystal silicon ingot. There is a distance, D, that extends along the surface of the melt between the single crystal silicon ingot and the sidewall of the crucible. An impact region of the melt surface at which doped particulate silicon is added to the melt is determined. The flow and melt speed of the doped particulate silicon in the melt is modeled. A particle size or weight of doped particulate silicon to be added to the melt during growth of the single crystal silicon ingot is selected based on the modeled flow and melt speed of the doped particulate silicon in the melt. Doped particulate silicon having the selected particle size is added to the melt in the impact region during growth of the single crystal silicon ingot.

Another aspect of the present disclosure is directed to a method for forming a single crystal silicon ingot. An initial charge of polycrystalline silicon is added to a crucible. The crucible has a floor and a sidewall that extends from the floor. The initial charge of polycrystalline silicon is heated to cause a silicon melt to form in the crucible. The silicon melt has a surface. A seed crystal is contacted with the silicon melt. The seed crystal is withdrawn from the melt to grow a single crystal silicon ingot. There is a distance, D, that extends along the surface of the melt between the single crystal silicon ingot and the sidewall of the crucible. Doped particulate silicon is added to the melt during growth of the single crystal silicon ingot. The concentration of dopant in the doped particulate silicon is at least 1×10¹⁴ atoms/cm³. The doped particulate silicon impacts the surface of the melt in an impact region that extends from 0.08*D from the silicon ingot and toward the crucible sidewall. The doped particulate silicon has a weight of less than 10 milligram (mg).

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section view of an ingot puller apparatus;

FIG. 2 is a top view of an ingot and crucible showing an impact region in the melt for addition of doped particulate silicon;

FIG. 3 includes boxplots of zero dislocation and zero dislocation yield in which doped particulate silicon having a size of 5 mg was added to the melt at a distance ratio of 0.08 to 0.1 between the crystal and the crucible sidewall;

FIG. 4 includes reproduced photos of doped particulate silicon cut from a doped single crystal silicon wafer;

FIG. 5 is a simulation of dopant behavior at different dropping positions of doped particulate silicon;

FIG. 6 is a simulation of the radial temperature profile of the melt free surface;

FIG. 7 is a model of the melt flow in cusp and magnetic field Czochralski methods;

FIG. 8 is a graph of the calculated and experimental resistivity profile during a counter-doping operation;

FIG. 9 is a graph of the maximum particle size of doped particulate silicon as a function of the distance ratio between the ingot and crucible sidewall;

FIG. 10 is a schematic view of a tool to crush a silicon wafer and photos of a crushed wafer; and

FIG. 11 is a reproduction of a silicon wafer that has been diced with a dicing tool.

Corresponding reference characters indicate corresponding parts throughout the drawings.

### DETAILED DESCRIPTION

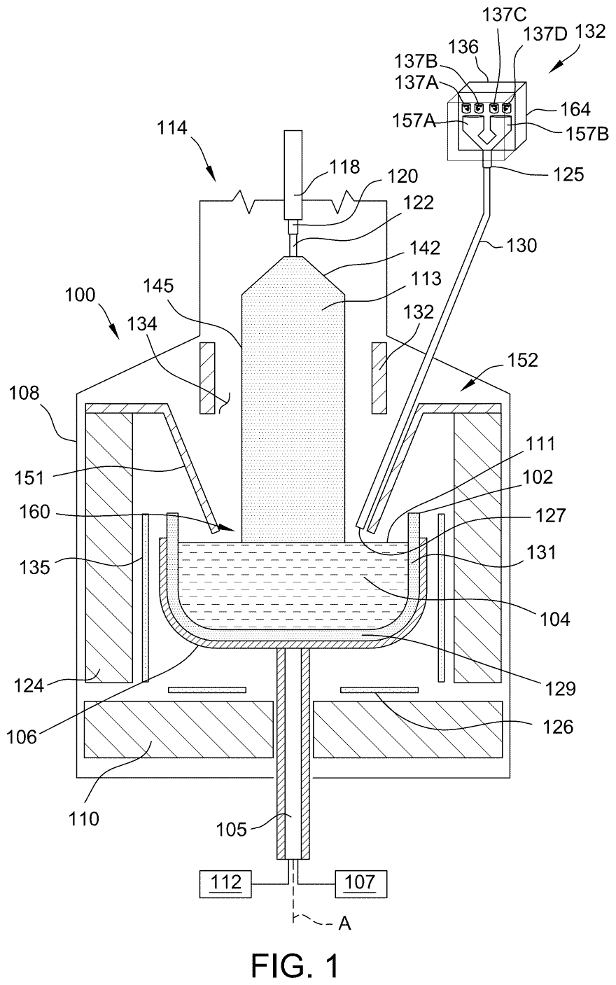

Provisions of the present disclosure relate to methods for doping a silicon melt with a solid-phase dopant during ingot growth. An example ingot puller apparatus (or more simply “ingot puller”) for growing a monocrystalline silicon ingot and for addition of dopant is indicated generally at “100” in FIG. 1. The ingot puller apparatus 100 includes a crystal puller housing 108 that defines a growth chamber 152 for pulling a silicon ingot 113 from a melt 104 of silicon. The ingot puller apparatus 100 includes a crucible 102 disposed within the growth chamber 152 for holding the melt 104 of silicon. The crucible 102 is supported by a susceptor 106.

The crucible 102 includes a floor 129 and a sidewall 131 that extends upward from the floor 129. The sidewall 131 is generally vertical. The floor 129 includes the curved portion of the crucible 102 that extends below the sidewall 131. Within the crucible 102 is a silicon melt 104 having a melt surface 111 (i.e., melt-ingot interface). The susceptor 106 is supported by a shaft 105. The susceptor 106, crucible 102, shaft 105 and ingot 113 have a common longitudinal axis A or “pull axis” A.

A pulling mechanism 114 is provided within the ingot puller apparatus 100 for growing and pulling an ingot 113 from the melt 104. The pulling mechanism 114 includes a pulling cable 118, a seed holder or chuck 120 coupled to one end of the pulling cable 118, and a seed crystal 122 coupled to the seed holder or chuck 120 for initiating crystal growth. One end of the pulling cable 110 is connected to a pulley (not shown) or a drum (not shown), or any other suitable type of lifting mechanism, for example, a shaft, and the other end is connected to the chuck 120 that holds the seed crystal 122. In operation, the seed crystal 122 is lowered to contact the melt 104. The pulling mechanism 114 is operated to withdraw the seed crystal 122 from the melt 104 and cause the seed crystal 122 to rise. This causes a single crystal ingot 113 to be pulled from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. As the ingot grows, the silicon melt 104 is consumed and the height of the melt in the crucible 102 decreases. The crucible 102 and susceptor 106 may be raised to maintain the melt surface 111 at or near the same position relative to the ingot puller apparatus 100.

A crystal drive unit (not shown) may also rotate the pulling cable 118 and ingot 113 in a direction opposite the direction in which the crucible drive unit 107 rotates the crucible 102 (e.g., counter-rotation). In embodiments using iso-rotation, the crystal drive unit may rotate the pulling cable 118 in the same direction in which the crucible drive unit 107 rotates the crucible 102. In addition, the crystal drive unit raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a quantity of solid-phase silicon such as polycrystalline silicon is charged to the crucible 102. The semiconductor or solar-grade material that is introduced into the crucible 102 is melted by heat provided from one or more heating elements. The ingot puller apparatus 100 includes bottom insulation 110 and side insulation 124 to retain heat in the puller apparatus 100. In the illustrated embodiment, the ingot puller apparatus 100 includes a bottom heater 126 disposed below the crucible floor 129. The crucible 102 may be moved to be in relatively close proximity to the bottom heater 126 to melt the polycrystalline charged to the crucible 102.

To form the ingot, the seed crystal 122 is contacted with the surface 111 of the melt 104. The pulling mechanism 114 is operated to withdraw the seed crystal 122 from the melt 104. The ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104. The ingot 113 has a central longitudinal axis A that extends through the crown portion 142 and a terminal end of the ingot 113.

The ingot puller apparatus 100 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 100 also includes a heat shield 151 disposed within the growth chamber 152 and above the melt 104 which shrouds the ingot 113 during ingot growth. The heat shield 151 defines a central passage 160 for receiving the ingot 113 as the ingot is pulled by the pulling mechanism 114. The ingot puller apparatus may include a magnetic coil to apply a cusp or horizontal magnetic field during ingot growth.

The ingot puller apparatus 100 includes a dopant feed system 132. The dopant feed system 132 includes a dopant feeder 164 and dopant tube 130 that extends through the ingot puller housing 108 for adding solid-phase dopant to the crucible 102. Solid-phase dopant passes through the dopant tube 130 to contact the melt 104 to cause the melt 104 to be doped. The dopant tube 130 includes an inlet 125 disposed exterior to the growth chamber 152 and an outlet 127 disposed in the growth chamber 152 and positioned relatively near the surface of the melt 104.

The dopant feeder 164 is disposed exterior to the growth chamber 152. The dopant feeder 164 includes a dopant feeder housing 136 and one or more dopant storage vessels or “cups” 137 disposed within the housing 136 for adding solid-phase dopant to the melt 104. In the illustrated embodiment, the dopant feeder 164 includes a first cup 137A, second cup 137B, third cup 137C, and fourth cup 137D. A process gas (e.g., argon) may be circulated through the dopant feeder 164. In the illustrated embodiment, because the dopant is within the dopant feeder housing 136 which seals the system from the ambient atmosphere, the dopant feed system 132 does not include an isolation valve. In other embodiments an isolation valve may be used. The dopant feeder housing 136 is external to the ingot puller housing 108.

A batch of doped particulate silicon is pre-loaded in each dopant cup 137 prior to ingot growth. During ingot growth, a rotation mechanism (not shown) may be actuated to sequentially rotate each cup 137 according to a predetermined doping protocol to dispense preloaded doped particulate silicon from the feeder 164, into the dopant tube 130, and into the melt 104. The dopant feeder 164 includes one or more funnels 157 (first and second funnels 157A, 157B being shown in the illustrated embodiment) disposed below the dopant cups 137. The funnels 157A, 157B are connected to the dopant tube 130.

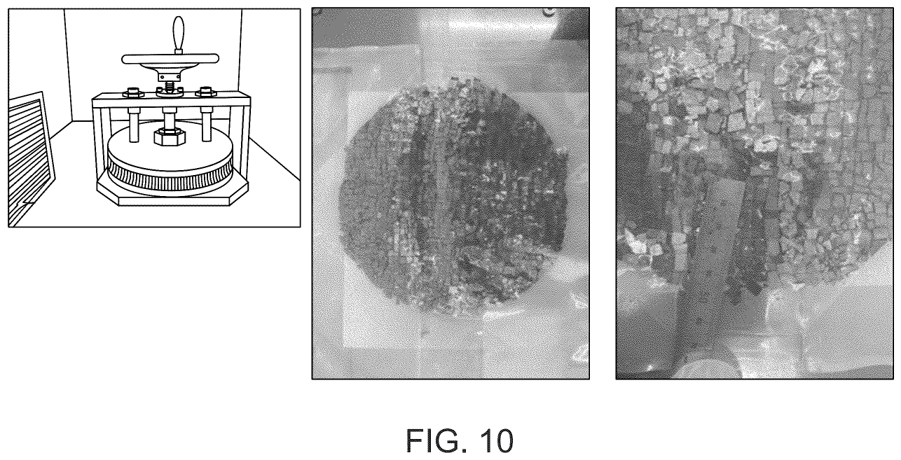

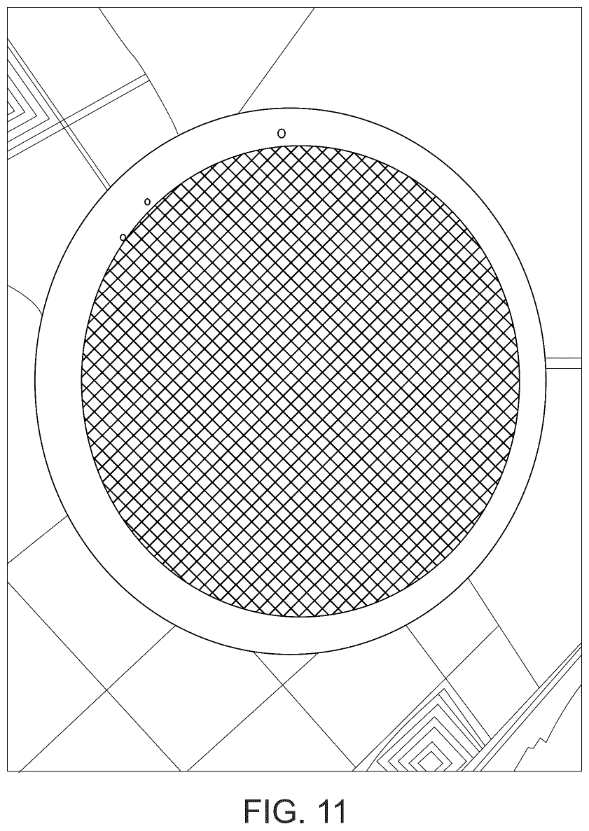

In accordance with embodiments of the present disclosure, doped particulate (i.e., solid-phase) silicon is added to the melt 104 during growth of the single crystal silicon ingot 113. Any suitable method may be used to produce the doped particulate silicon (which may also be referred to herein as “silicon alloy”) For example, the particulate silicon may be silicon that is crushed or cut from a silicon wafer (i.e., the particulate silicon is single crystal silicon). To cut the particulate silicon, a wafer may be scribed and broken apart. The wafer may be crushed with a tool (FIG. 10) or diced with a dicing saw (FIG. 11).

The concentration of dopant in the particulate silicon may be at least 1×10¹⁴ atoms/cm² (e.g., 1×10¹⁴ atoms/cm³ to 1×10²⁰ atoms/cm³). In other embodiments, the concentration is at least 1×10¹⁵ atoms/cm³, at least 5×10¹⁵ atoms/cm³, at least 1×10¹⁶ atoms/cm³, at least 1×10¹⁷ atoms/cm³, or at least 1×10¹⁶ atoms/cm³. The doped particulate silicon may be P-type or N-type. In some embodiments, the dopant in the particulate silicon is boron (e.g., having a concentration of at least 1×10¹⁵ atoms/cm³). The doped particulate silicon includes an amount of dopant that is above an intrinsic amount of dopant in particulate silicon (e.g., that would be present in polycrystalline silicon grown by the Siemens method or in a fluidized bed reactor).

In some embodiments of the present disclosure, the initial melt 104 is doped initially before or after meltdown and before growth of the silicon ingot. This first dopant may be of a type different than the second dopant (e.g., the dopant added during ingot growth as in counter-doping embodiments). For example, the first dopant may be P-type with the second dopant being N-type. Alternatively, the first dopant may be N-type with the second dopant being P-type.

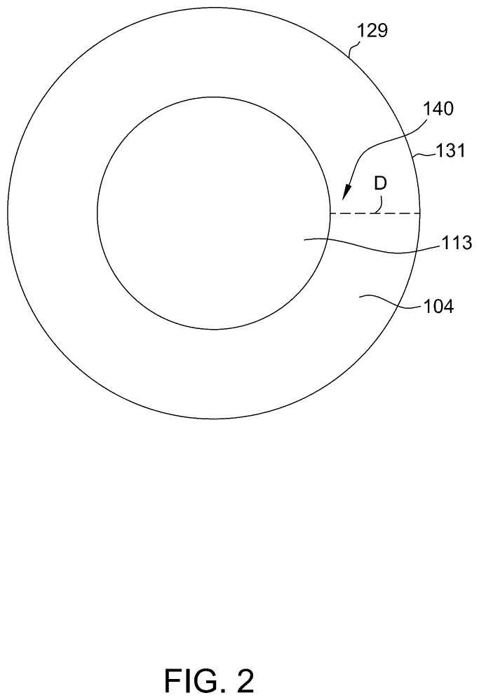

Referring now to FIG. 2, there is a distance D that extends along the surface of the melt 104 between the main body of the single crystal silicon ingot 113 and the sidewall 131 of the crucible 102. The doped silicon particulate drops into the melt 104 in an impact region 140 in which the particulate silicon impacts the surface of the melt 104. The position of the impact region 140 may be selected based on the particle size of the doped particulate silicon. Once the particle size and/or weight of the doped particulate silicon that will be added during ingot growth is determined, the flow and melt speed of the doped particulate silicon in the melt may be modeled (see Example 4 below). For example, the flow and melt speed of the particulate silicon in the melt may include modeling the likelihood of loss of zero dislocation in the single crystal silicon ingot (e.g., correlating a size or weight of the particulate silicon to an impact region at which loss of zero dislocation is least likely to occur).

The impact region of the melt surface at which doped particulate silicon is added to the melt is selected based on the modeled melt flow and melt speed of the particulate silicon in the melt. The position of the tube 130 between the ingot 113 and crucible sidewall 131 may be pre=set in the ingot puller apparatus (i.e., during set-up of the hotzone) or may be adjusted by a dopant tube translation device (not shown). In some embodiments, the hotzone limits the position of the dopant tube (e.g., because of the heat shield design) such as to 0.08*D to 1.0*D.

In accordance with some embodiments of the present disclosure, the weight of the doped silicon particles is less than 10 milligrams (mg) (e.g., at least 50%, at least 75%, at least 90%, at least 95%, at least 99% or substantially all of the particles have a weight less than 10 mg). The weight and/or size of the doped silicon particles may be controlled to be less than 10 mg by screening the doped particulate silicon prior to addition to the melt. In other embodiments, the weight of the silicon particles is less than 9 mg, less than 7 mg, less than 5 mg, or from 1 mg to 10 mg or from 1 mg to 5 mg. The particulate dopant may have a thickness typical for single crystal silicon wafers (e.g. 0.5 mm to 1 mm).

In some embodiments, the amount of doped particulate silicon added to the melt is based on a measured resistivity of a single crystal silicon wafer that is crushed or cut to produce the doped particulate silicon,

In some embodiments of the present disclosure, the impact region extends from 0.08*D to 0.1*D from the silicon ingot (e.g., with the weight of silicon particles being less than 10 mg to reduce or eliminate LZD). In impact regions from about 0.1*D to 0.6*D, the weight of the silicon particles may be less than 400 mg (e.g., 25 to 400 mg). In impact regions greater than 0.6*D, the weight of the silicon particles may be less than 800 mg.

Compared to conventional methods for doping a silicon melt, the methods of the present disclosure have several advantages. By controlling the size of the doped particulate silicon added to the melt, the zero dislocation success ratio may be increased (e.g., when the addition location is limited such as by reflector design). Use of doped particulate silicon enables fast and effective melting at the melt surface once impact is made with the melt surface (i.e., 100% efficiency in doping) and allows conventional doping feed systems to be used. Use of relatively small particles directly onto the melt surface may reduce melt vibration (e.g., in cusp magnetic field) which can cause loss of zero dislocation in the growing crystal. Use of doped particulate silicon enables relatively easy control and manufacture of dopant.

### EXAMPLES

The processes of the present disclosure are further illustrated by the following Examples. These Examples should not be viewed in a limiting sense.

### Example 1: Effect of the Size of Doped Particulate Silicon on Loss of Zero Dislocation

The dopant tube in a 200 mm ingot crystal puller was positioned such that the doped particulate silicon impacted the melt surface in a region between 0.08*D and 0.1*D (“D” being the distance between the silicon ingot and the crucible sidewall with D being zero at the crystal edge) during ingot growth (i.e., re-doping or counter-doping). As shown in Table 1, a smaller size of doped particulate silicon (as represented by less total grams of piece) produces a higher zero dislocation success ratio (e.g., size of 0.01 gram or less).

TABLE 1
Zero Dislocation Success for Different
Sizes of Doped Particulate Silicon

| | 0.005 | 0.01 | 0.015 |
|---|---|---|---|
| Trial | gram | gram | gram |
| 1 | No | No | Yes |
| 2 | No | No | Yes |
| 3 | No | No | Yes |
| 4 | No | No | Yes |
| 5 | No | No | Yes |
| 6 | No | Yes | Yes |
| 7 | No | Yes | Yes |
| 8 | No | Yes | Yes |
| 9 | No | Yes | Yes |
| 10 | No | Yes | Yes |
| Frequency (%) | 0 | 50 | 100 |

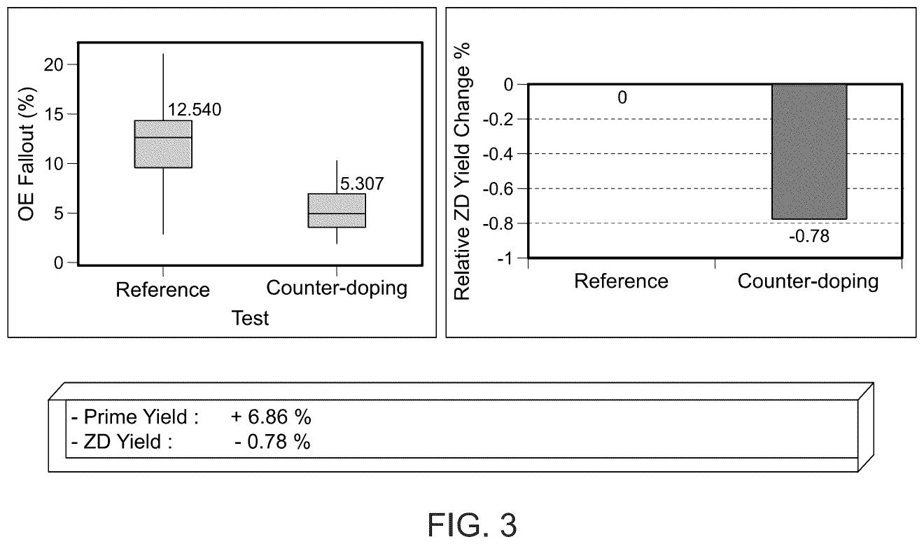

This resulted in higher zero dislocation yield with lower zero dislocation yield as shown in FIG. 3. Despite lower zero dislocation yield, higher prime yield was achieved by extending the prime length related to the resistivity specification range. The right side bar graph of FIG. 3 shows the relative impact of zero dislocation yield with and without counter-doping. Counter-doping increases loss of zero dislocation relative to no counter-doping (“reference”). The increase in loss of zero dislocation is offset by less “fallout” (as shown in the left side box plot) which is the amount of the opposite end of the crystal that is out of specification which results in an increase in overall prime output.

### Example 2: Melt Vibration as a Function of Size of Doped Particulate Silicon

Dropping solid dopant pieces directly onto the melt surface generates melt vibration (e.g., in cusp magnetic field) which can cause loss of zero dislocation (LZD) in the growing crystal. Table 2 illustrates the qualitative comparison of melt vibration as a function of dopant size. A smaller weight of dopant particles reduced melt vibration. This result is dependent on the radial landing position of dopant alloy on the melt free surface (distance from crystal surface), the melt flow velocity caused by crucible rotation and magnetic field, and the magnetic field type such as cusp or horizontal flux.

TABLE 2
Detection of Melt Vibration for Different Sized Particles

| | 0.005 | 0.01 | 0.015 |
|---|---|---|---|
| Trial | gram | gram | gram |
| 1 | No | Yes | No |
| 2 | No | No | No |
| 3 | No | No | Yes |
| 4 | No | No | No |
| 5 | No | No | No |
| 6 | No | Yes | No |
| 7 | No | No | Yes |
| 8 | No | Yes | No |
| 9 | No | No | No |
| 10 | No | No | No |
| Frequency (%) | 0 | 30 | 20 |

### Example 3: Zero Dislocation Success as a Function of Size of Doped Particulate Silicon

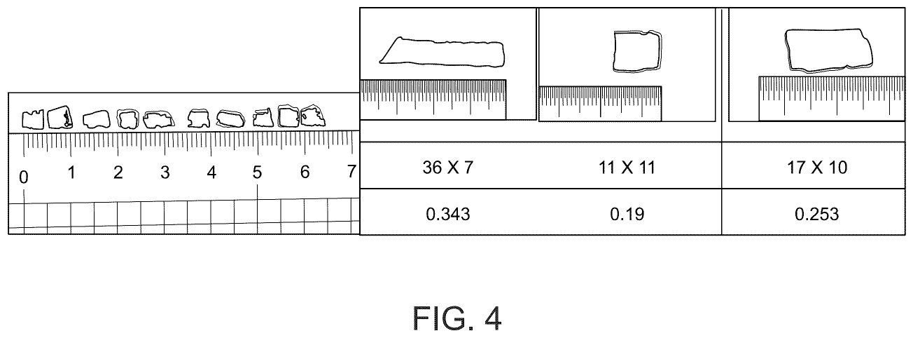

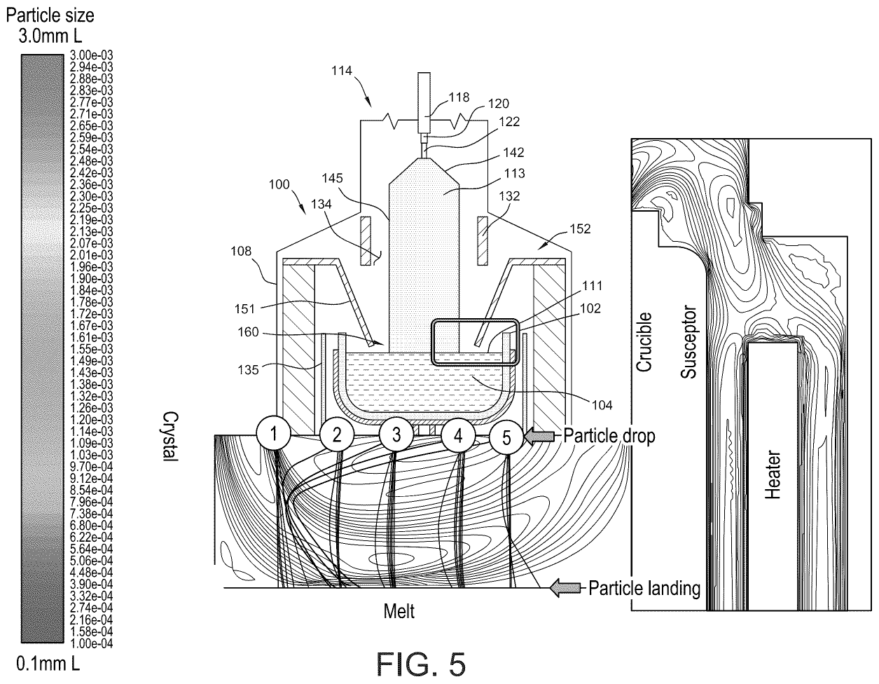

Dopant alloy shown in FIG. 4 (n-type, crushed n++ wafer, with less than 6 mm diagonal length) was fed on the melt free surface through a pre-installed quartz feeding tube in a 32 inch ingot puller apparatus. The feeding position was the third feeding point shown in FIG. 5 (about crystal radius (R)/2*D distance between crystal edge and the crucible wall or about 0.28*D). FIG. 5 shows the dopant behavior from different dropping positions with a distribution 0.1˜3.0 mm diagonal length with 0.725 mm thickness. The contour line indicates the argon gas velocity.

The dropping position mostly indicates the landing position on the melt surface as shown in FIG. 5, but fine dopant particle may be affected by the vortex directly below the reflector bottom. The path of the fine particle will be different depending on the design of the reflector and can be selected to be safe from loss of zero dislocation by taking the vortex path into account.

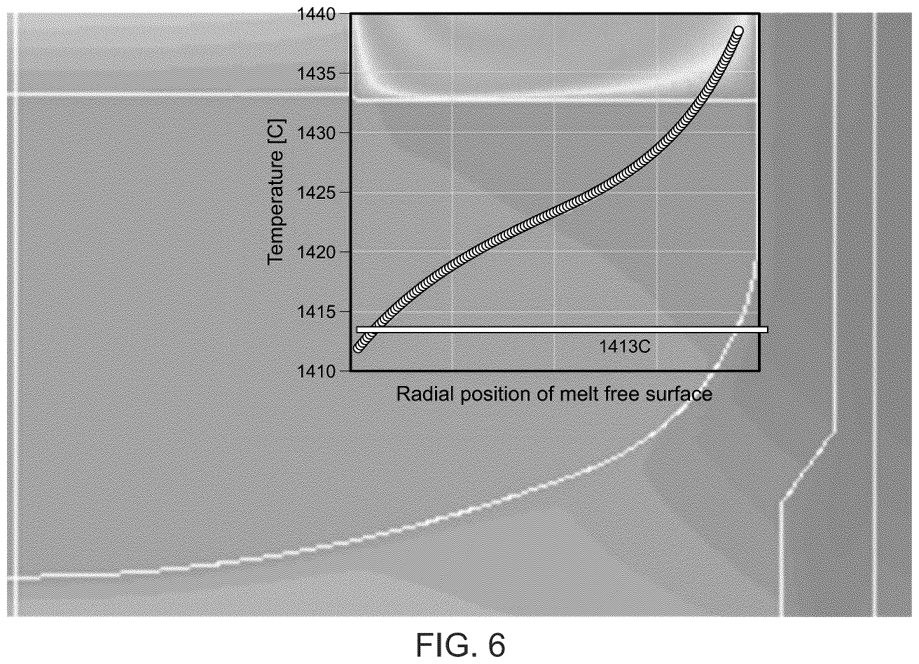

FIG. 6 shows the radial temperature profile on the melt free surface. The landing position dictates the melting speed of the dropped dopant pieces because the radial temperature distribution of the melt free surface increases from the crystal to the crucible wall. FIG. 6 shows that pieces landing nearby the crucible wall will melt very quickly, even for large size dopant pieces. The radial temperature profile of the melt free surface varies in different hotzone configurations. The temperature profile is higher than the melting point of silicon (except the meniscus area). This illustrates that dropped silicon pieces will melt quickly even if they are dropped to the melt free surface at a 0.08 to 0.1 distance ratio between the crystal and the crucible.

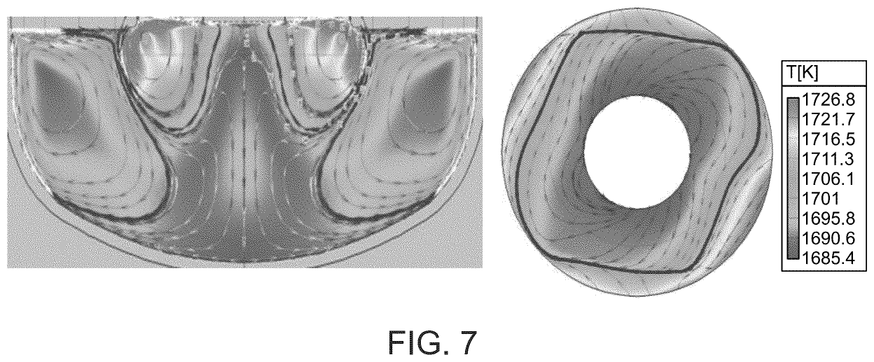

FIG. 7 shows images of the modeled melt flow path of cusp (side view of melt region) and horizontal (top view of melt free surface) magnet processes. The melt flow path of the cusp field illustrates that the floating pieces will move from the crucible surface to the crystal surface. The horizontal magnet tends to push out the floating pieces towards the crucible wall. Doped particulate silicon has a higher potential to traverse to the crystal surface in the cusp magnet process if it does not melt relatively quickly once it hits the melt surface.

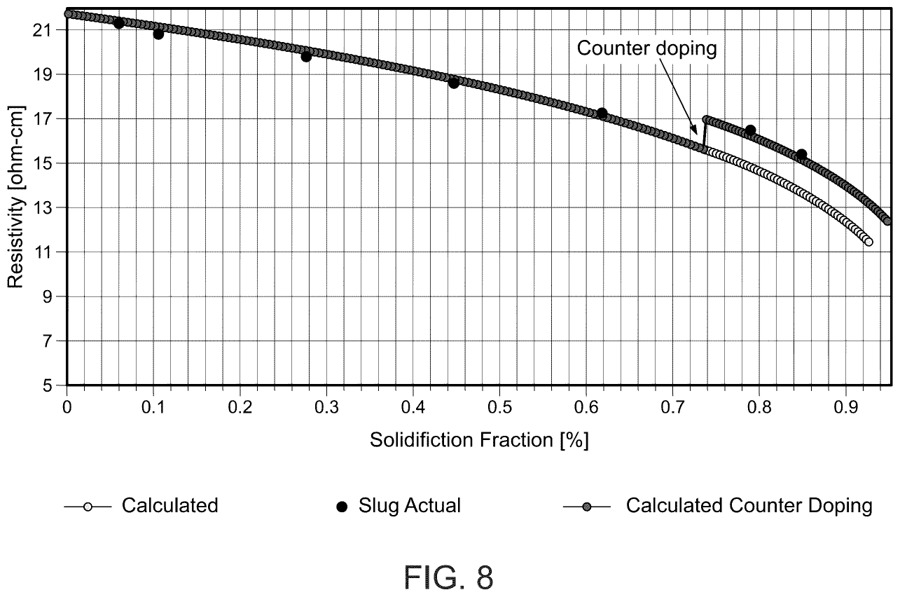

The experiment result from the middle doping position of FIG. 5 indicates that the actual resistivity follows the calculated curve well as shown in FIG. 8. Particulate silicon containing phosphorous was dropped at ˜0.76 solidification fraction during P-type crystal growth, and resistivity was instantly increased by the N-type dopant. Since doping efficiency was 100%, resistivity after doping is very well matched with calculated value as shown in FIG. 8.

### Example 4: Modeling Maximum Particle Size of Doped Particulate Silicon as a Function of Drop Location

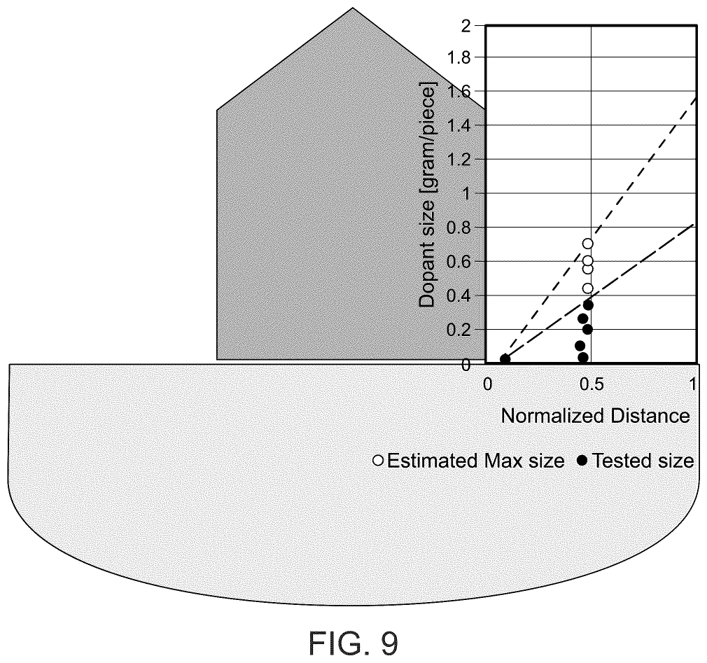

FIG. 9 illustrates the determined maximum dopant size versus landing position from the crystal surface as modeled by the methods described herein. There is a relationship between the size of dopant and zero dislocation success as a function of the landing position, which is directly affected by the temperature of the melt surface. The temperature of the melt free surface where the dopant lands dictates the time constant required to melt the particle. Melt flow convection (also dependent on magnet type) will dictate the transient movement of the particle upon landing, either toward or away from the growing meniscus. Combined together, landing further from the crystal meniscus provides a higher ratio of zero dislocation success. Experimental results showed that doped particulate silicon having a size of less than 0.01 gram may be used at the 0.08˜0.1 distance ratio between the crystal and crucible. Results indicate that for a 0.4˜0.5 distance ratio between crystal and crucible, larger (0.35 gram/particle) enables zero dislocation. By extrapolation of results, FIG. 9 plots the estimated maximum size of particles (weight based) as a function of normalized distance between the crystal meniscus and the crucible wall.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for forming a single crystal silicon ingot comprising:
adding an initial charge of polycrystalline silicon to a crucible, the crucible having a floor and a sidewall that extends from the floor;
heating the initial charge of polycrystalline silicon to cause a silicon melt to form in the crucible, the silicon melt having a surface;
contacting a seed crystal with the surface of the silicon melt;
withdrawing the seed crystal from the melt to grow a single crystal silicon ingot, there being a distance, D, that extends along the surface of the melt between the single crystal silicon ingot and the sidewall of the crucible;
determining an impact region of the melt surface at which doped particulate silicon is added to the melt;
modeling the flow and melt speed of the doped particulate silicon in the melt;
selecting a particle size or weight of doped particulate silicon to be added to the melt during growth of the single crystal silicon ingot based on the modeled flow and melt speed of the doped particulate silicon in the melt; and
adding doped particulate silicon having the selected particle size to the melt in the impact region during growth of the single crystal silicon ingot.

2. The method as set forth in claim 1 comprising cutting or crushing one or more single crystal silicon wafers to produce the doped particulate silicon.

3. The method as set forth in claim 1 wherein modeling the flow and melt speed of the doped particulate silicon in the melt includes modeling the likelihood of loss of zero dislocation in the single crystal silicon ingot.

4. The method as set forth in claim 1 wherein modeling the flow and melt speed of the doped particulate silicon in the melt includes correlating a size or weight of the doped particulate silicon to an impact region at which loss of zero dislocation is least likely to occur.

5. A method for forming a single crystal silicon ingot comprising:
adding an initial charge of polycrystalline silicon to a crucible, the crucible having a floor and a sidewall that extends from the floor;
heating the initial charge of polycrystalline silicon to cause a silicon melt to form in the crucible, the silicon melt having a surface;
contacting a seed crystal with the silicon melt;
withdrawing the seed crystal from the melt to grow a single crystal silicon ingot, there being a distance, D, that extends along the surface of the melt between the single crystal silicon ingot and the sidewall of the crucible; and
adding doped particulate silicon to the melt during growth of the single crystal silicon ingot, the concentration of dopant in the doped particulate silicon being at least 1×10¹⁴ atoms/cm³, the doped particulate silicon impacting the surface of the melt in an impact region that extends from 0.08*D from the silicon ingot and toward the crucible sidewall, the doped particulate silicon having a weight of less than 10 milligram (mg).

6. The method as set forth in claim 5 wherein the impact region extends from 0.08*D from the silicon ingot to 0.1*D from the silicon ingot.

7. The method as set forth in claim 5 wherein the doped particulate is crushed or cut from one or more single crystal silicon wafers.

8. The method as set forth in claim 5 comprising cutting a single crystal silicon wafer to produce the doped particulate silicon.

9. The method as set forth in claim 5 comprising:
determining the resistivity of the single crystal silicon wafer; and
determining the amount of doped particulate silicon added to the melt based, at least in part, on the resistivity of the single crystal silicon wafer.

10. The method as set forth in claim 5 wherein the dopant is a second dopant, the method comprising doping the melt with a first dopant before the single crystal silicon ingot is grown, the first dopant being of a type different than a type of the second dopant.

11. The method as set forth in claim 10 wherein the first dopant is p-type and the second dopant is n-type.

12. The method as set forth in claim 10 wherein the first dopant is n-type and the second dopant is p-type.

13. The method as set forth in claim 5 wherein the dopant is boron.

14. The method as set forth in claim 13 wherein the concentration of boron in the doped particulate silicon is from 1×10¹⁴ atoms/cm³ to 1×10²⁰ atoms/cm³.

15. The method as set forth in claim 5 comprising pre-loading doped particulate silicon into one or more dopant storage vessels before ingot growth, the vessel being disposed within a dopant feeder housing to seal the vessel from an ambient atmosphere, the vessel being external to an ingot puller housing.

16. The method as set forth in claim 15 comprising dispensing preloaded doped particulate silicon from the vessel during ingot growth, the preloaded doped particulate silicon passing through a dopant tube that extends through an ingot puller housing.

17. The method as set forth in claim 5 wherein the doped particulate silicon has a weight of less than 9 mg.

18. The method as set forth in claim 5 wherein the doped particulate silicon has a weight less than 5 mg.

19. The method as set forth in claim 5 wherein the doped particulate silicon has a weight from 1 mg to 10 mg.
